(19) United States
(12) Patent Application Publication
(10) Pub. No.: US 2011/0222334 A1
(43) Pub. Date: Sep. 15, 2011

(54) SPIN TRANSFER TORQUE MRAM, AND WRITE METHOD AND READ METHOD THEREFOR

(75) Inventor: Masaki AOKI, Kawasaki (JP)

(73) Assignee: FUJITSU LIMITED, Kawasaki-shi (JP)

(21) Appl. No.: 13/036,127

(22) Filed: Feb. 28, 2011

(30) Foreign Application Priority Data
Mar. 15, 2010 (JP) 2010-56927

(51) Int. Cl. G11C 11/16

(52) U.S. Cl. 365/158

(57) ABSTRACT

A method of writing data into a memory cell of spin transfer torque magnetoresistive random access memory includes writing a first data into a first memory cell that includes a first magnetic-tunnel-junction element and a first selection transistor wherein an end of the first memory cell is connected to a first signal line and a different end of the first memory cell is connected to a common signal line during a first period, and writing a second data which is an opposite of the first data into the second memory cell that includes a second magnetic-tunnel-junction element and a second selection transistor wherein an end of the second memory cell is connected to a second signal line and a different end of the second memory cell is connected to the common signal line during a second period following the first period.

### CROSS-REFERENCE TO RELATED APPLICATIONS

This application is based upon and claims the benefit of priority from the prior Japanese Patent Application No. 2010-56927 filed on Mar. 15, 2010, the entire contents of which are incorporated herein by reference.

### FIELD

The present invention relates to a spin transfer torque magnetoresistive random access memory (MRAM), and a write method and a read method therefor.

### BACKGROUND

An MRAM is a nonvolatile magnetic memory storing information about the magnetization state of a magnetic tunnel junction (MTJ) element as data. Hitherto, a wiring current-magnetic field-type MRAM provided to perform the data writing by changing the magnetization state of the MTJ element with the power of a magnetic field generated with a current passed through surrounding wiring has been available.

Further, a spin transfer torque MRAM provided to directly feed a current through the MTJ element and change the magnetization state of the MTJ element with the power of a spin torque generated with the current has been available. Compared to the wiring current-magnetic field-type MRAM, the spin transfer torque MRAM may not include wiring specifically designed for the data writing and may perform the data writing with a reduced current, for example. Usually, the spin transfer torque MRAM has a 1T-1MTJ-type memory-cell configuration including a single MTJ element and a single selection transistor provided to select the single MTJ element.

Since the memory cell of the spin transfer torque MRAM has been downsized, variations in the characteristics of the MTJ elements tend to increase due to the limitations of processing technology. The increase in the variations in the characteristics of the MTJ elements often makes it difficult to write/read data into/from the memory cell.

### SUMMARY

According to aspects of embodiments, a method of writing data into a memory cell of spin transfer torque magnetoresistive random access memory includes writing a first data into a first memory cell that includes a first magnetic-tunnel-junction element and a first selection transistor wherein an end of the first memory cell is connected to a first signal line and a different end of the first memory cell is connected to a common signal line during a first period, and writing a second data which is an opposite of the first data into the second memory cell that includes a second magnetic-tunnel-junction element and a second selection transistor wherein an end of the second memory cell is connected to a second signal line and a different end of the second memory cell is connected to the common signal line during a second period following the first period.

The object and advantages of the invention will be realized and attained at least by the elements, features, and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

Each of FIGS. 1A and 1B illustrates exemplary operating principles of an MRAM;

FIG. 2 is a circuit diagram of an MRAM according to a first embodiment;

FIG. 3 illustrates an exemplary cell configuration of the MRAM of the first embodiment;

FIG. 4 is a flowchart illustrating an exemplary write operation of the MRAM of the first embodiment;

Each of FIGS. 5A to 5D illustrates an exemplary write operation of the MRAM of the first embodiment;

FIG. 6 is a flowchart illustrating an exemplary read operation of the MRAM of the first embodiment;

Each of FIGS. 7A and 7B is a timing chart illustrating an exemplary write operation of an MRAM according to a second embodiment;

FIG. 8 is a graph illustrating exemplary write characteristics of an MTJ element;

FIG. 9A is a timing chart illustrating an exemplary write operation of an MRAM according to a comparison example; and

FIG. 9B is a timing chart illustrating the write operation of the MRAM of the second embodiment.

### DESCRIPTION OF EMBODIMENTS

Preferred embodiments will be explained with reference to accompanying drawings.

Each of FIGS. 1A and 1B illustrates the operating principles of a spin transfer torque MRAM. As illustrated in each of FIGS. 1A and 1B, a magnetic tunnel junction (MTJ) element provided to store data includes a fixed layer 10 in a fixed magnetization state, a free layer 12 in a changeable magnetization state, and a barrier layer 14 placed between the fixed layer 10 and the free layer 12. Each of the fixed layer 10 and the free layer 12 includes a ferromagnetic material, and the barrier layer 14 includes a tunnel magnetoresistance film.

The spin transfer torque MRAM stores data based on the resistance value of the MTJ element, the resistance value being determined in accordance with the relative magnetization directions of the fixed layer 10 and the free layer 12. The magnetization direction of the free layer 12 can be arbitrarily changed by the passage of a current through the MTJ element.

When a current I is passed from the free layer 12 toward the fixed layer 10, an electron e moves from the fixed layer 10 toward the free layer 12 as illustrated in FIG. 1A. When the electron e passes through the fixed layer 10, the spin direction of the electron e coincides with the direction of the fixed layer 10, and the magnetization state of the free layer 12 becomes equivalent to that of the fixed layer 10 due to the spin torque of the electron e passing through the fixed layer 10. The above-described state where the magnetization directions of the fixed layer 10 and the free layer 12 are equal to each other is referred to as the “parallel state” where the MTJ element enters the low-resistance state. Further, writing data to make the MTJ element enter the parallel state will be referred to as “parallelization writing”.

When the current I is passed from the fixed layer 10 toward the free layer 12, the electron e moves from the free layer 12 toward the fixed layer 10 as illustrated in FIG. 1B. When the electron e is reflected off the fixed layer 10, the spin direction of the electron e coincides with a direction opposite to that of the fixed layer 10, and the magnetization state of the free layer 12 becomes opposite to that of the fixed layer 10 due to the spin torque of the electron e reflected off the fixed layer 10. The above-described state where the magnetization directions of the fixed layer 10 and the free layer 12 are opposite to each other is referred to as the “antiparallel state” where the MTJ element enters the high-resistance state. Further, writing data to make the MTJ element enter the antiparallel state will be referred to as “antiparallelization writing”.

Data is read from the MTJ element by the passage of a read current through the MTJ element. The read current is smaller than a current passed through the MTJ element, the current being passed to write data, and is large enough not to cause a magnetic reversal in the free layer 12. When the current passed through the MTJ element is large, it is determined that the MTJ element is in the “parallel state”. When the current passed through the MTJ element is small, it is determined that the MTJ element is in the “antiparallel state”. Logical values “0” and “1” are assigned to the parallel state and the antiparallel state of the MTJ element, and vice versa, to store the data.

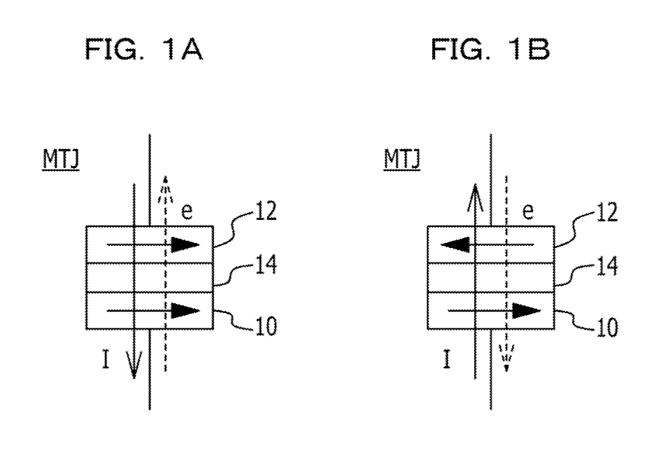

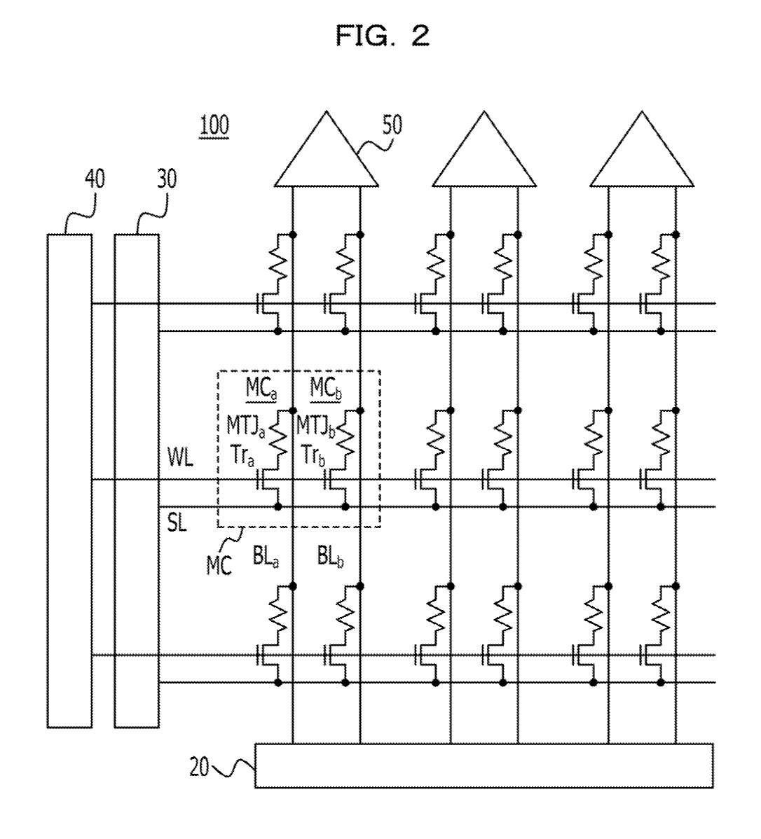

FIG. 2 is a circuit diagram of an MRAM 100 according to a first embodiment. The MRAM 100 includes a plurality of spin transfer torque MRAM memory cells MC arranged in an array form, a bit-line drive circuit 20, a source-line drive circuit 30, a word-line drive circuit 40, and a sense amplifier 50. Each of the memory cells MC has two memory cells MCₐ and MC_{b} which pair up with each other and store 1-bit data. Each of the memory cells MCₐ and MC_{b} is connected to a common source line SL and a common word line WL. Further, the memory cell MCₐ is connected to a bit line BLₐ and the memory cell MC_{b} is connected to a bit line BL_{b}.

The memory cell MCₐ includes a magnetic-tunnel-junction element MTJₐ and a selection transistor Trₐ connected thereto. The gate terminal of the selection transistor Trₐ is connected to the word line WL, and one of input/output terminals (diffusion layer) is connected to the source line SL and the other is connected to the magnetic-tunnel-junction element MTJₐ. Of the terminals of the magnetic-tunnel-junction element MTJₐ, a terminal opposite to that connected to the selection transistor Trₐ is connected to the bit line BLₐ.

The memory cell MC_{b} includes a magnetic-tunnel-junction element MTJ_{b} and a selection transistor Tr_{b} connected thereto. The gate terminal of the selection transistor Tr_{b} is connected to the word line WL, and one of input/output terminals (diffusion layer) is connected to the source line SL and the other is connected to the magnetic-tunnel-junction element MTJ_{b}. Of the terminals of the magnetic-tunnel-junction element MTJ_{b}, a terminal opposite to that connected to the selection transistor Tr_{b} is connected to the bit line BL_{b}.

One of the ends of each of the bit lines BLₐ and BL_{b} is connected to the bit-line drive circuit 20. The bit-line drive circuit 20 controls the potential of each of the bit lines BLₐ and BL_{b}, and supplies the write current and the read current to each of the memory cells MC. The other end of each of the bit lines BLₐ and BL_{b} is connected to the sense amplifier 50. The sense amplifier 50 reads data from each of the memory cells MC by comparing the potentials of the bit lines BLₐ and BL_{b} with each other.

The source line SL is connected to the source-line drive circuit 30 and the word line WL is connected to the word-line drive circuit 40. The source-line drive circuit 30 controls the potential of the source line SL and the word-line drive circuit 40 controls the potential of the word line WL.

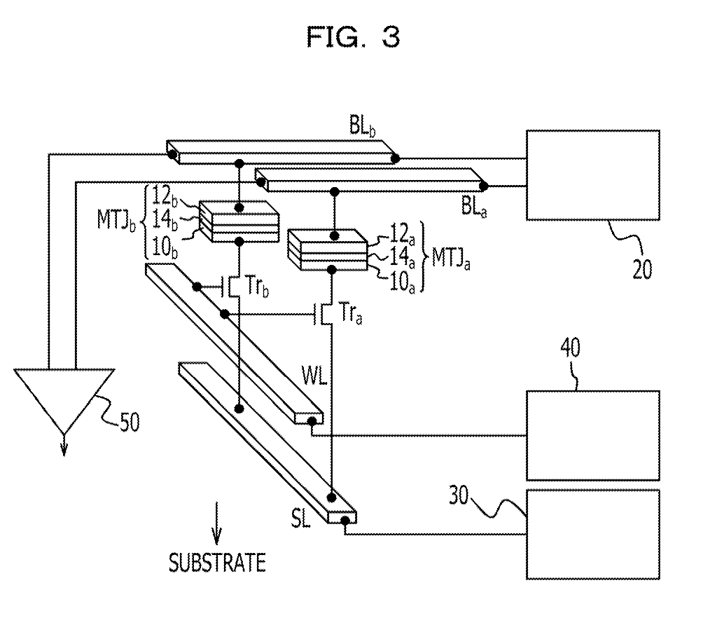

FIG. 3 illustrates an exemplary cell configuration of the MRAM 100. When viewed from the side near a substrate (not shown), the source line SL, the word line WL, the selection transistor Tr, the magnetic-tunnel-junction element MTJ, and the bit line BL are provided in that order. Further, the source line SL and the word line WL are parallel to each other, and the bit lines BLₐ and BL_{b} are arranged in a direction intersecting the source line SL and the word line WL.

Thus, each of the memory cells MC of the MRAM 100 according to the first embodiment is a 2T-2MTJ-type memory cell including two selection transistors (Trₐ and Tr_{b}) and two MTJ elements (MTJₐ and MTJ_{b}). The source line SL and the word line WL are shared between the two memory cells (MCₐ and MC_{b}), and the bit lines (BLₐ and BL_{b}) are individually connected to each of the memory cells. Hereinafter, the methods of writing data into and reading data from the MRAM 100 will be described.

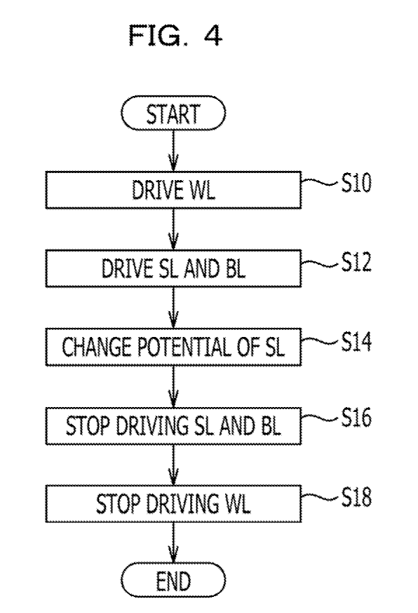

FIG. 4 is a flowchart illustrating an exemplary write operation performed with the MRAM 100. The word-line drive circuit 40 drives the word line WL to a specified potential through operation (S10). Accordingly, the selection transistors Trₐ and Tr_{b} provided in each of the memory cells MC are turned on, and the magnetic-tunnel-junction elements MTJₐ and MTJ_{b} are electrically connected to the source line SL.

The source-line drive circuit 30 drives the source line SL to a specified potential, and the bit-line drive circuit 20 drives the bit lines BLₐ and BL_{b} to individual different specified potentials through operation (S12). At that time, the potential difference between one of the two bit lines BLₐ and BL_{b}, and the source line SL is large enough to allow the write current to flow into the MTJ element. Further, the potential difference between the other of the two bit lines BLₐ and BL_{b}, and the source line SL is small enough (e.g., the same potential) not to allow the write current to flow into the MTJ element. Consequently, data is written into either of the magnetic-tunnel-junction elements MTJₐ and MTJ_{b} (that is, either of the memory cells MCₐ and MC_{b}).

During operation (S14), the source-line drive circuit 30 switches the potential of the source line SL to a specified potential different from the potential set through operation (S12). On the other hand, each of the bit lines BLₐ and BL_{b} is maintained at the potential set through operation (S12). At that time, the potential difference between one of the two bit lines BLₐ and BL_{b} (the bit line for which the data writing is not performed through operation (S12)), and the source line SL is large enough to allow the write current to flow into the MTJ element. Further, the potential difference between the other of the two bit lines BLₐ and BL_{b} (the bit line for which the data writing is performed through operation (S12)), and the source line SL is small enough (e.g., the same potential) not to allow the write current to flow into the MTJ element. Consequently, data is written into one of the magnetic-tunnel-junction elements MTJₐ and MTJ_{b} (that is, the memory cells MCₐ and MC_{b}) so that the data is written into the MTJ element for which the data writing is not performed through operation (S12). The data written into the MTJ element at that time is the opposite of the data written through operation (S12) at all times.

The source-line drive circuit 30 stops driving the source line SL and the bit-line drive circuit 20 stops driving the bit lines BLₐ and BL_{b} through operation (S16). The word-line drive circuit 40 stops driving the word line WL through operation (S18). When the above-described operations are performed, the write operation performed with the MRAM 100 is completed.

Each of FIGS. 5A, 5B, 5C, and 5D illustrates the write operation performed with the MRAM 100 according to the first embodiment. In the following description, the first half of a data-writing operation, which is operation (S12), is determined to be a first period T₁ and a memory cell into which data is written in the first period T₁ is determined to be a first memory cell. Further, the latter half of the data-writing operation (operation (S14)), which follows the first period T₁, is determined to be a second period T₂ and a memory cell into which data is written in the second period T₂ is determined to be a second memory cell. The length of the first period T₁ is equivalent to that of the second period T2 in the first embodiment. Still further, data written into the memory cell through the parallelization writing, which makes the resistance of the MTJ element low, is determined to be “0”, and that written into the memory cell through the antiparallelization writing, which makes the resistance of the MTJ element high, is determined to be “1”.

Further, an MTJ element and a selection transistor that are provided in the first memory cell are individually determined to be a first MTJ element and a first selection transistor, and a bit line connected to the first memory cell is determined to be a first bit line. Further, an MTJ element and a selection transistor that are provided in the second memory cell are individually determined to be a second MTJ element and a second selection transistor, and a bit line connected to the second memory cell is determined to be a second bit line.

FIG. 5A is a timing chart illustrating the case where the data “0” is written into the memory cell MCₐ and the data “1” is written into the memory cell MC_{b}, and FIG. 5B illustrates the direction of a current flowing at that time. As illustrated in FIG. 5A, the word line WL reaches a high (H) level as indicated by the sign A, and each of the source lines SL and the bit line BLₐ reaches the H level as indicated by the signs B and C. At that time, no current flows between the source line SL and the bit line BLₐ, and a write current I₁ flows from the source line SL to the bit line BL_{b} as illustrated in FIG. 5B. Consequently, the data “1” is written into the memory cell MC_{b} (antiparallelization).

The source line SL is switched from the H level to a low (L) level as indicated by the sign D. At that time, no current flows between the source line SL and the bit line BL_{b}, and a write current I₂ flows from the bit line BLₐ to the source line SL. Consequently, the data “0” is written into the memory cell MCₐ (parallelization). The bit line BLₐ is in the L level as indicated by the sign E, and the word line WL is in the L level as indicated by the sign F. The data writing is hereby finished.

FIG. 5C is a timing chart illustrating the case where the data “1” is written into the memory cell MCₐ and the data “0” is written into the memory cell MC_{b}, and FIG. 5D illustrates the direction of a current flowing at that time. As illustrated in FIG. 5C, the word line WL reaches the H level as indicated by the sign G, and each of the source lines SL and the bit line BL_{b} reaches the H level as indicated by the signs H and I. At that time, no current flows between the source line SL and the bit line BL_{b}, and a write current I₃ flows from the source line SL to the bit line BLₐ as illustrated in FIG. 5D. Consequently, the data “1” is written into the memory cell MCₐ (antiparallelization).

The source line SL is switched from the H level to the L level as indicated by the sign J. At that time, no current flows between the source line SL and the bit line BLₐ, and a write current I₄ flows from the bit line BL_{b} to the source line SL. Consequently, the data “0” is written into the memory cell MC_{b} (parallelization). The bit line BL_{b} is in the L level as indicated by the sign K, and the word line WL is in the L level as indicated by the sign L. The data writing is hereby finished.

According to FIGS. 5A and 5B, the data “1” is written into the memory cell MC_{b} at first, and the data “0” is written into the memory cell MCₐ. That is, the memory cell MC_{b} functions as the first memory cell and the memory cell MCₐ functions as the second memory cell. On the other hand, according to FIGS. 5C and 5D, the data “1” is written into the memory cell MCₐ at first, and the data “0” is written into the memory cell MC_{b}. That is, the memory cell MCₐ functions as the first memory cell and the memory cell MC_{b} functions as the second memory cell. Thus, which of the two memory cells MCₐ and MC_{b} should function as the first memory cell (the second memory cell) depends on circumstances.

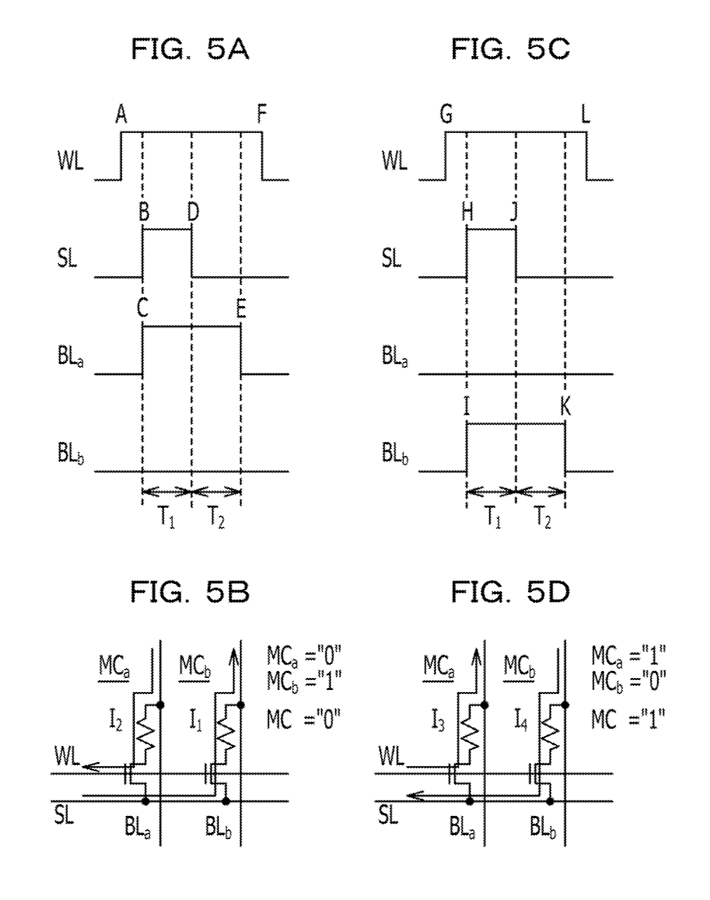

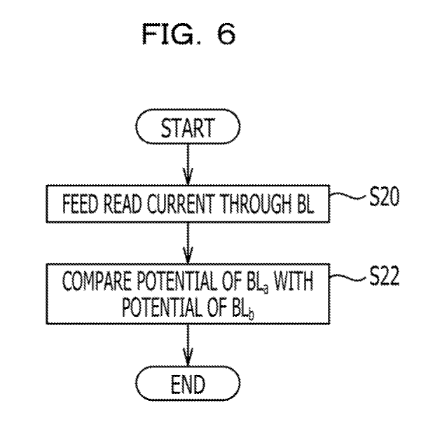

FIG. 6 is a flowchart illustrating an exemplary read operation performed with the MRAM 100. The bit-line drive circuit 20 feeds the read current through the bit lines BLₐ and BL_{b} through operation (S20). The read current is a substantially constant current which is smaller than the write current and large enough not to change the magnetization state of the MTJ element. When the data “0” is stored in the memory cell in that state, the MTJ element is in the parallel (low resistance) state so that the potential of each of the bit lines BLₐ and BL_{b} is significantly decreased. On the other hand, when the data “1” is stored in the memory cell, the MTJ element is in the antiparallel (high resistance) state. Accordingly, a decrease in the potential of each of the bit lines BLₐ and BL_{b} is less significant than in the case where the data “0” is stored in the memory cell (or the potential of each of the bit lines BLₐ and BL_{b} is hardly decreased).

The sense amplifier 50 reads data stored in the memory cell MC by comparing the potentials of the bit lines BLₐ and BL_{b} with each other through operation (S22). For example, when the data “0” is stored in the memory cell MCₐ and the data “1” is stored in the memory cell MC_{b}, the potential of the bit line BL_{b} becomes higher than that of the bit line BLₐ. The above-described state is defined as the state where the data “0” is stored in the memory cell MC. On the other hand, when the data “1” is written into the memory cell MCₐ and the data “0” is written into the memory cell MC_{b}, the potential of the bit line BLₐ becomes higher than that of the bit line BL_{b}. The above-described state is defined as the state where the data “1” is stored in the memory cell MC. Here, the relationship between the resistance state of the memory cell MC and each of the memory cells MCa and MCb, and the logical values “1” and “0” may be arbitrarily determined, or may be opposite to that described in the present embodiment.

Thus, according to the MRAM 100 of the first embodiment, first data is stored in the first memory cell and second data which is the opposite of the first data is stored in the second memory cell. According to a 1T-1MTJ-type memory cell that has been used, the potential of the bit line BL should be compared to a reference potential lying somewhere in between the H level and the L level at the data-reading time. Compared to the 1T-1MTJ-type memory cell, the 2T-2MTJ-type memory cell of the MRAM 100 of the first embodiment reads data from the memory cell by comparing the potential of the bit line BLₐ with that of the bit line BL_{b} so that a read margin which is nearly twice as large as that obtained in the past is ensured. Consequently, it becomes possible to reduce the effect of variations in the characteristics of the MTJ elements, and write and read data into and from the memory cell with stability.

Hitherto, a 2T-2MTJ-type memory cell configuration has been used for a wiring current-magnetic field-type MRAM. However, a spin transfer torque MRAM such as the MRAM 100 is significantly different from the wiring current-magnetic field-type MRAM in point of the configuration and operating principles of the memory cell. More specifically, the MRAM 100 is configured so that the source line SL and the word line WL are shared between the memory cells MCₐ and MC_{b} that are connected to the individual bit lines BLₐ and BL_{b}. Therefore, the MRAM 100 may not include a word line specifically designed for the data writing. Further, according to a write method performed with the MRAM 100, the first data is written into the first memory cell in the first period T₁ included in the data-writing cycle and the second data, which is the opposite of the first data, is written into the second memory cell in the second period T₂ following the first period T₁.

The data writing is performed by relatively changing the potentials of the bit lines BLₐ and BL_{b}, and the source line SL. Here, it is preferable that the potential of each of the bit lines BLₐ and BL_{b} that are provided as separate signal lines have a value fixed throughout the first period T₁ and the second period T₂, and the potential of the source line SL provided as a common signal line have a value changing between the first period T₁ and the second period T₂. Consequently, it becomes possible to reduce the frequency of changing the potential and write data with efficiency.

In the MRAM 100 of the first embodiment, the MTJ element is connected to the bit line BL and the selection transistor Tr is connected to the source line SL. However, the positional relationship between the MTJ element and the selection transfer Tr may be reversed so that the MTJ element is connected to the source line SL and the selection transistor Tr is connected to the bit line BL. However, since the MTJ element is vulnerable to heat, providing the selection transistor Tr near the source line SL (that is, near the substrate) as illustrated in FIG. 3 is advantageous for making a manufacturing process easier.

According to a second embodiment, the time of data writing is exemplarily changed between the first half and the latter half of the data-writing cycle. Since the memory-cell configuration and the flowchart of the write operation of the second embodiment are substantially the same as those of the first embodiment, the details thereof will be omitted.

Each of FIGS. 7A and 7B is a timing chart illustrating a write operation performed with an MRAM according to the second embodiment. FIG. 7A is a timing chart illustrating the case where the data “0” is written into the memory cell MCₐ and the data “1” is written into the memory cell MC_{b}, which corresponds to FIG. 5A described in the first embodiment. In FIG. 7A, the first period T₁ where the data “1” is written into the memory cell MC_{b} is longer than the second period T₂ where the data “0” is written into the memory cell MCₐ. Other operations are substantially the same as those illustrated in FIG. 5A and the direction of a flowing current is substantially the same as that illustrated in FIG. 5B.

FIG. 7B is a timing chart illustrating the case where the data “1” is written into the memory cell MCₐ and the data “0” is written into the memory cell MC_{b}, which corresponds to FIG. 5C described in the first embodiment. In FIG. 7B, the first period T₁ where the data “1” is written into the memory cell MCₐ is longer than the second period T₂ where the data “0” is written into the memory cell MC_{b}. Other operations are substantially the same as those illustrated in FIG. 5C and the direction of a flowing current is substantially the same as that illustrated in FIG. 5D.

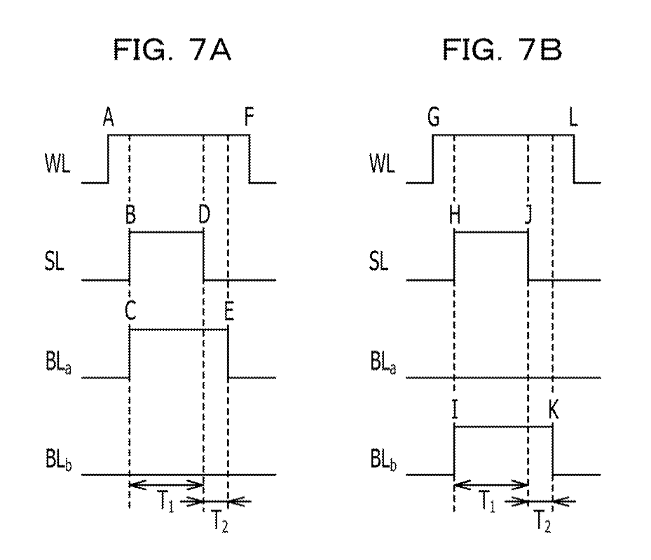

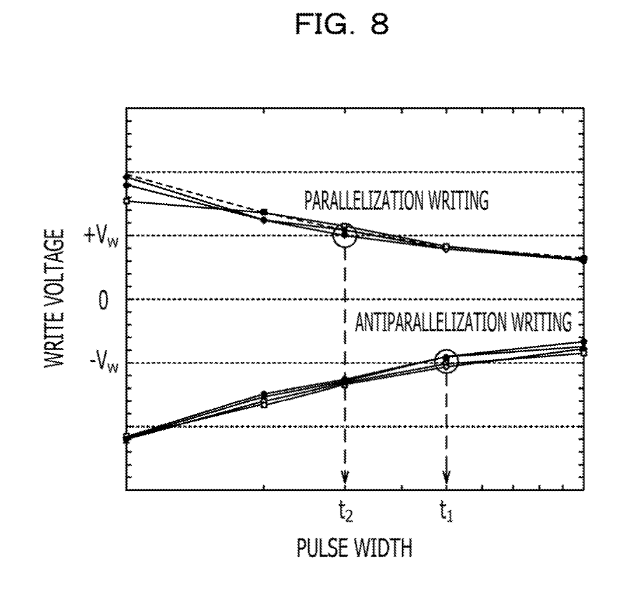

FIG. 8 is a graph illustrating exemplary write characteristics of the MTJ element. The lateral axis indicates the pulse width of a write voltage and the vertical axis indicates the magnitude of the write voltage (the lateral axis is illustrated as a logarithmic scale). The characteristics of the MTJ element for the write voltage are changed between the case where the parallelization writing is performed and the case where the antiparallelization writing is performed. That is, when write voltages having the same absolute value (+V_{W} and −V_{W}) is applied, a time t₁ consumed for performing the antiparallelization writing is longer than a time t₂ consumed for performing the parallelization writing.

In each of FIGS. 7A and 7B, the time period where the data “1” is written (the time period where the antiparallelization writing is performed) is longer than that where the data “0” is written (the time period where the parallelization writing is performed). Accordingly, data can be written into the memory cell MC with efficiency and the overall data-writing time can be reduced.

According to the writing operation performed with the MRAM 100 in each of the first and second embodiments (FIGS. 5A to 5D and 7), the level of the source line SL is determined to be the H level in the first period T₁ and the L level in the second period T₂. However, the level of the source line SL may be reversed, that is, the level of the source line SL may be determined to be the L level in the first period T₁ and the H level in the second period T₂. In spite of that, it is preferable that the level of the source line SL be determined according to the methods of the first and second embodiments due to the following reasons.

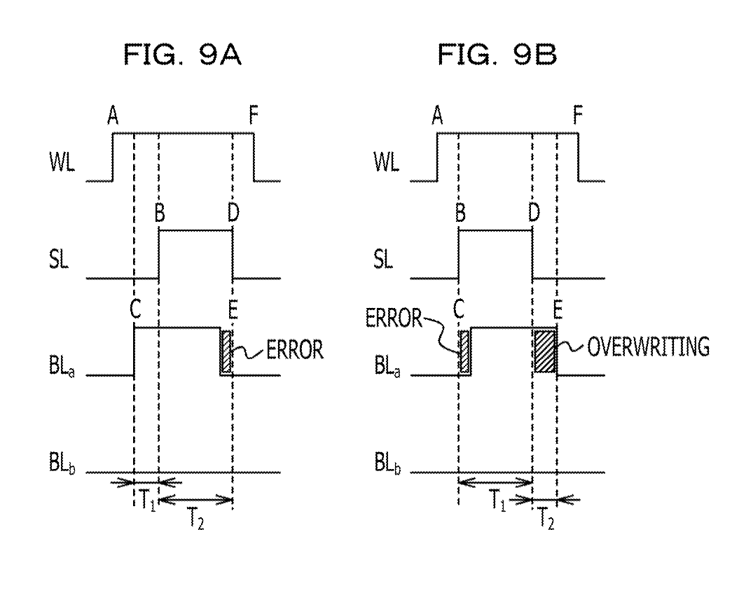

FIG. 9A is a timing chart illustrating an exemplary write operation performed with an MRAM according to a comparison example, and FIG. 9B is a timing chart illustrating the write operation performed with the MRAM of the second embodiment. When the potential of the source line SL is switched from the L level to the H level and that of the bit line BLₐ reaches the H level as illustrated in FIG. 9A, the data “0” is written into the memory cell MCₐ in the first period T₁. When the bit line BLₐ responds (the switching from the H level to the L level) earlier than expected in the latter half of the second period T₂, a write error occurs, that is, the data “0” written into the memory cell MCₐ is deleted and the data “1” is written instead. Since the erroneously written data “1” is not corrected through a subsequent write operation, the error data is stored in the memory cell MCₐ.

On the other hand, when the potential of the source line SL is switched from the H level to the L level and that of the bit line BLₐ reaches the H level as illustrated in FIG. 9B, the data “0” is written into the memory cell MCₐ in the second period T₂. When the bit line BLₐ responds (the switching from the L level to the H level) later than expected in the first half of the first period T₁, a different write error occurs, that is, the data “1” is written into the memory cell MCₐ in the first period T1 where no data is usually written.

However, according to FIG. 9B, the potential of the source line SL is in the L level and that of the bit line BLₐ is in the H level in the second period T₂ and the data “0” is written into the memory cell MCₐ so that the erroneously written data “1” is overwritten with the data “0”. Further, even though the bit line BLₐ responds (the switching from the H level to the L level) somewhat earlier or later than expected when the second period T₂ is finished, the written data is not affected by the response of the bit line BLₐ.

Thus, the configuration illustrated in FIG. 9B allows for overwriting and correcting data before the data-writing cycle is finished even though the write error occurs due to the deviation of response of each of the bit line BL and the source line SL. Accordingly, it is preferable that the potential of the source line SL, the potential being attained during the first period T₁, be higher than that attained during the second period T₂.

In each of the first and second embodiments, a memory device including the spin-transfer-torque MRAM memory cell is provided. However, the spin-transfer-torque MRAM memory cell may be used for any purpose other than the memory device. For example, using the spin-transfer-torque MRAM memory cell for a flip-flop circuit allows for storing information about the state of a voltage in a nonvolatile manner and/or storing information about part of operations performed with a logic LSI in the nonvolatile manner with the spin-transfer-torque MRAM memory cell.

The bit lines BLₐ and BL_{b} that are described in each of the first and second embodiments correspond to individual first and second signal lines. The first signal line is either of the bit lines BLₐ and BL_{b}, which is connected to a memory cell into which data is written during the first period T₁. Further, the second signal is either of the bit lines BLₐ and BL_{b}, which is connected to a memory cell into which data is written during the second period T₂. Further, the source line SL described in each of the first and second embodiments corresponds to a common signal line.

Thus, the embodiments have been described. Without being limited to the specific embodiments, the present invention can be modified and/or changed in various ways within the scope of the appended claims.

All examples and conditional language recited herein are intended for pedagogical purposes to aid the reader in understanding the invention and the concepts contributed by the inventor to furthering the art, and are to be construed as being without limitation to such specifically recited examples and conditions. Although the embodiment(s) of the present inventions have been described in detail, it should be understood that the various changes, substitutions, and alterations could be made hereto without departing from the spirit and scope of the invention.

What is claimed is:

1. A method of writing data into a memory cell of spin transfer torque magnetoresistive random access memory, comprising:
writing a first data into a first memory cell that includes a first magnetic-tunnel-junction element and a first selection transistor wherein an end of the first memory cell is connected to a first signal line and a different end of the first memory cell is connected to a common signal line during a first period, and
writing a second data which is opposite of the first data into the second memory cell that includes a second magnetic-tunnel-junction element and a second selection transistor wherein an end of the second memory cell is connected to a second signal line and a different end of the second memory cell is connected to the common signal line during a second period following the first period.

2. The method of writing the data into the memory cell of spin transfer torque magnetoresistive random access memory according to claim 1,
wherein a potential of each of the first and second signal lines has a value fixed throughout the first and second periods, and
wherein a potential of the common signal line has a value changed between the first and second periods.

3. The method of writing the data into the memory cell of spin transfer torque magnetoresistive random access memory according to claim 2,
wherein, the potential of the common signal line, which is attained in the first period, is higher than the potential of the common signal line, which is attained in the second period.

4. The method of writing the data into the memory cell of spin transfer torque magnetoresistive random access memory according to claim 1,
wherein, of the first and second periods, a length of a period where antiparallelization writing is performed is greater than a length of a period where parallelization writing is performed.

5. A memory cell of spin transfer torque magnetoresistive random access memory comprising:
a first memory cell that includes a first magnetic-tunnel-junction element and a first selection transistor, wherein an end of the first memory cell is connected to a first signal line and a different end of the first memory cell is connected to a common signal line, and first data is stored in the first memory cell; and
a second memory cell that includes a second magnetic-tunnel-junction element and a second selection transistor, wherein an end of the second memory cell is connected to a second signal line and a different end of the second memory cell is connected to the common signal line and second data which is an opposite of the first data is stored in the second memory cell.

6. A method of reading data from a memory cell of spin transfer torque magnetoresistive random access memory,
wherein the memory cell includes:
a first memory cell that includes a first magnetic-tunnel-junction element and a first selection transistor, wherein an end of the first memory cell is connected to a first signal line and a different end of the first memory cell is connected to a common signal line, and first data is stored in the first memory cell; and
a second memory cell that includes a second magnetic-tunnel-junction element and a second selection transistor, wherein an end of the second memory cell is connected to a second signal line and a different end of the second memory cell is connected to the common signal line and second data which is an opposite of the first data is stored in the second memory cell,
reading a data by feeding a read current through the first and second signal lines, and comparing a potential of the first signal line with a potential of the second signal line.
